(19) United States
(12) Patent Application Publication
(10) Pub. No.: US 2015/0316418 A1
(43) Pub. Date: Nov. 5, 2015

(54) Infrared Sensor Having a Microstructure with a Plurality of Thermocouples and a Carrier Element

(71) Applicant: SIEMENS AKTIENGESELLSCHAFT, München (DE)

(72) Inventors: Harry Hedler, Germering (DE); Michael Georg Wick, München (DE)

(21) Appl. No.: 14/653,994

(22) PCT Filed: Oct. 23, 2013
(86) PCT No.: PCT/EP2013/072190

§ 371 Date: Jun. 19, 2015

(30) Foreign Application Priority Data
Dec. 21, 2012 (DE) 10 2012 224 224.4

(51) Int. Cl. G01J 5/14; H01L 35/32; H01L 35/34; G01J 5/02; H01L 27/16

(52) U.S. Cl. CPC G01J 5/14; G01J 5/02; H01L 27/16; H01L 35/34; H01L 35/32

(57) ABSTRACT

The embodiments relate to an infrared sensor having a microstructure with a plurality of thermocouples and a carrier element, wherein each thermocouple of the plurality of thermocouples includes a first sensor element having a first Seebeck coefficient and a second sensor element having a second Seebeck coefficient, wherein the first and the second sensor element extend from a front side of the carrier element through the carrier element to a rear side of the carrier element and wherein the first and the second sensor element are electrically connected to one another in a region of the upper side of the carrier element, wherein the carrier element forms a substrate for an integrated circuit, which is configured on the rear side of the carrier element and includes at least one component which is electrically connected to the first the second sensor element.

### CROSS-REFERENCE TO RELATED APPLICATIONS

The present patent document is a §371 nationalization of PCT Application Serial Number PCT/EP2013/072190, filed Oct. 23, 2013, designating the United States, which is hereby incorporated by reference, and this patent document also claims the benefit of DE 10 2012 224 224.4, filed on Dec. 21, 2012, which is also hereby incorporated by reference.

### TECHNICAL FIELD

The present embodiments relate to an infrared sensor having a microstructure with a plurality of thermocouples and a carrier element. The present embodiments also relate to a method for producing a microstructure with a plurality of thermocouples and a carrier element.

### BACKGROUND

An infrared sensor of the type mentioned and a corresponding production method are known, for example, from DE 10 2009 043 413 B3. Accordingly, an infrared sensor may be formed as a three-dimensional microstructure, in which individual thermocouples are respectively formed by two semiconductor rods aligned parallel to one another, which protrude in a self-supporting manner from a carrier element of the sensor. At their free ends, the two semiconductor rods are electrically connected to one another, so that they together form a double rod. Furthermore, the two semiconductor rods are formed from materials with different Seebeck coefficients. Between the rods, a so-called thermoelectric force may be measured, (e.g., an electric voltage that occurs when there is a difference in temperature between the free end of the double rod), to which the two semiconductor rods are connected, and its end at the bottom of the sensor. Each of the double rods may in this case represent a picture element (e.g., pixel) in an image area of an infrared sensor.

Such infrared sensors may, for example, be incorporated in a thermal imaging camera. In order to provide sufficient image resolution, infrared sensors with several thousands of thermocouples may be used in such thermal imaging cameras. To be able to evaluate the thermocouples and to be able to measure the thermoelectric voltage between two sensor elements, corresponding measuring circuits are used. As a result of the high number of sensor elements that have to be evaluated, the measuring electronics require considerable installation space. Moreover, there is the problem of the electrical and mechanical connection between the chip of the infrared sensor and the measuring electronics.

### SUMMARY AND DESCRIPTION

The scope of the present invention is defined solely by the appended claims and is not affected to any degree by the statements within this summary. The present embodiments may obviate one or more of the drawbacks or limitations in the related art.

It is an object of the present embodiments to provide an infrared sensor of the type mentioned at the beginning that is of a more compact construction and may be produced at lower cost.

The infrared sensor includes a microstructure with a plurality of thermocouples and a carrier element, each thermocouple of the plurality of thermocouples including a first sensor element having a first Seebeck coefficient and a second sensor element having a second Seebeck coefficient. The first and second sensor elements extend from a front side of the carrier element through the carrier element to a rear side of the carrier element, and the first and second sensor elements are electrically connected to one another in a region of the upper side of the carrier element. The carrier element forms a substrate for an integrated circuit, which is formed on the rear side of the carrier element and includes at least one component that is electrically connected to the first and second sensor elements.

The infrared sensor is produced by a microtechnical production method. The infrared sensor may be produced from a semiconductor material, e.g., silicon. The infrared sensor has a plurality of thermocouples. For example, the infrared sensor has several thousands of thermocouples. Each thermocouple includes two sensor elements, which have a different Seebeck coefficient. The individual sensor elements may in this case take the form of rods or the form of hollow cylinders. The individual sensor elements may be arranged parallel to one another and are formed in such a way that the sensor elements protrude substantially perpendicularly from a front side of a carrier element. A first and a second sensor element are respectively electrically connected to one another at the free ends. The sensor elements extend from the free end through the carrier element to the rear side of the carrier element. At the rear side of the carrier element, the thermoelectric voltage between the first and the second sensor element may be tapped.

The carrier element forms a substrate for an integrated circuit. The integrated circuit is formed on the rear side of the carrier element. In particular, the integrated circuit is integrated directly in the carrier element or the semiconductor material. The integrated circuit may include one or more electronic components, which are produced in particular on the basis of CMOS technology. The at least one component of the integrated circuit is in this case electrically connected to the first and second sensor elements. The integrated circuit may also include corresponding conductor tracks. This allows at least parts of the evaluation circuit for the thermocouples to be integrated on the semiconductor substrate from which the infrared sensor is also microtechnically produced. In this way, a more compact structure of the infrared sensor may be made possible. Moreover, the number of acts for the constructing and connecting techniques is reduced.

The at least one component may be designed to record an electric voltage between the first and the second sensor element. On the rear side of the carrier element there is the so-called “cold end” of the respective thermocouples of the infrared sensor. At the free ends of the sensor elements, at which they are electrically connected, there is the so-called “hot end”. So if there is a difference in temperature between the “hot end” and the “cold end”, a thermoelectric voltage forms between the first and the second sensor element. This may then be further processed directly by a corresponding component on the rear side of the carrier structure. In this way the signal of each of the thermocouples may be recorded directly at the location in which it occurs. In this way, measuring errors that may arise, for example, as a result of long measuring lines may be reduced.

In one embodiment, the integrated circuit includes an amplifier and/or an analog-to-digital converter. The integrated circuit may also include corresponding components designed to further process appropriately the signal of the respective thermocouples or the thermoelectric voltage. For example, the measuring signal may be appropriately amplified. For this purpose, amplifiers may be formed by transistors that are produced by using CMOS technology. The integrated circuit may also include elements with which the measuring signal or the thermoelectric voltage may be digitized. In this case, it is also conceivable that the integrated circuit includes corresponding logic elements. This makes it possible to output a preprocessed signal or a plurality of signals directly at the infrared sensor or the sensor chip.

In a further refinement, the integrated circuit includes a temperature sensor for recording a temperature on the rear side of the carrier element. In this way, in addition to the thermoelectric voltage, the temperature at the “cold end” of the respective thermocouples may also be recorded. In this case, a plurality of temperature sensors may also be provided in the integrated circuit. The signals recorded by the temperature sensors may be further processed directly by the integrated circuit. This allows, for example, an effective temperature compensation of the measuring signal to be made possible.

The first sensor element may be formed as a hollow profile and the second sensor element is arranged in the first sensor element. The first sensor element may have the basic form of a hollow cylinder or else, for example, also be formed as an angular tube. The second sensor element is arranged in the first sensor element. In other words, the first, hollow sensor element is, for example, completely filled by the second sensor element or else the second sensor element is for its part a hollow profile, which, for example, extends coaxially in the first sensor element. The two sensor elements fitted one within the other allow a particularly compact structure to be made possible, a structure in which the individual thermocouples are close together. This allows many individual thermocouples for individual pixels to be arranged on a small image area.

In a further embodiment, the integrated circuit has solder contacts. The solder contacts may, for example, be formed as pads. A solder may have been applied to the pads. Similarly, the use of a corresponding solder paste is conceivable. This makes easy electrical contacting of the infrared sensor possible. This in turn simplifies the installation of the infrared sensor in a housing or a thermal imaging camera.

The method for producing a microstructure with a plurality of thermocouples and a carrier element includes providing a substrate material, which forms a substrate for an integrated circuit, forming the integrated circuit on a rear side of the substrate material, the integrated circuit including at least one component, forming a plurality of wells, which extend from the rear side of the substrate material into the substrate material, arranging a first material with a first Seebeck coefficient in a respective interior space of a first predetermined number of the plurality of wells to form a respective first sensor element, arranging a second material with a second Seebeck coefficient in a respective interior space of a second predetermined number of the plurality of wells to form a respective second sensor element and removing the substrate material, starting from a front side of the substrate material, and thereby exposing at least one region of the first and/or second sensor elements.

The starting material for producing the microstructure that forms an infrared sensor is a substrate material that is formed in particular from a semiconductor material. On a rear side of the substrate material there is formed an integrated circuit. In this case, CMOS technology may be used. The integrated circuit may be appropriately masked or passivated. A plurality of wells are etched into the substrate material from the rear side. A first material with a first Seebeck coefficient is introduced into a plurality of the wells. This may take place, for example, by chemical vapor deposition (CVD). Moreover, a second material with a Seebeck coefficient that is different from the first material is introduced into the wells. In this case, the first material and the second material may also be introduced into the interior space of the same well. As an alternative to this, the first material is introduced into the interior space of a first well and the second material is introduced into the interior space of a second, neighboring well. Moreover, the first material and the second material are electrically connected to one another in a predetermined region. The substrate material is removed, starting from the front side, in order to expose the individual sensor elements. In this way an easy production method for an infrared sensor may be provided, a method in which the evaluation electronics are integrated on the sensor chip.

The first material may be arranged in the respective interior space of the wells, after that an electrically insulating material is applied to the first material and after that the second material is applied to the electrically insulating material. The first material is applied in the interior space of each of the plurality of wells. In this case, the electrically insulating material may be applied in such a way that it only covers the first material in certain regions. Subsequently, the second material is applied to the electrically insulating material. This allows an easy production method for producing a plurality of thermocouples to be provided, the two sensor elements of the respective thermocouple being arranged one within the other.

A semiconductor material with a first semiconductor layer, a second semiconductor layer, and an insulating layer arranged between the semiconductor layers may be provided as substrate material. Thus, for example, a so-called SOI wafer may be used. The first semiconductor layer may form the substrate for the integrated circuit. The electrically insulating layer may have the effect that the switching times, the power consumption and, in particular, leakage currents of the integrated circuit may be reduced. The second semiconductor layer may be used for producing the individual thermocouples by methods of microsystem technology.

In the case of one embodiment, for forming the wells, the first semiconductor layer is etched by a dry-chemical etching method and the second semiconductor layer is etched by an electrochemical etching method. Dry etching methods that are customary in microsystem technology may be used for the first semiconductor layer, which at the same time serves as a substrate for the integrated circuit. The wells may have here a diameter of 2 to 10 μm. For etching the second semiconductor layer, which may have a greater layer thickness that the first semiconductor layer, an electrochemical etching method may be used. In particular, the so-called PAECE method (Photo Assisted Electrochemical Etching) may be used. With this method, high aspect ratios may be achieved.

The advantages and developments described above in connection with the infrared sensor may in the same way be transferred to the method.

### BRIEF DESCRIPTION OF THE DRAWINGS

FIG. 1 depicts a schematic representation of an example of a substrate material for the microtechnical production of an infrared sensor in a perspective view.

FIG. 2 to FIG. 5 depict schematic representations of examples of cross-sectional views of the substrate material, which illustrate the production method of the infrared sensor.

FIG. 6 depicts a schematic representation of an example of the infrared sensor in a perspective representation.

### DETAILED DESCRIPTION

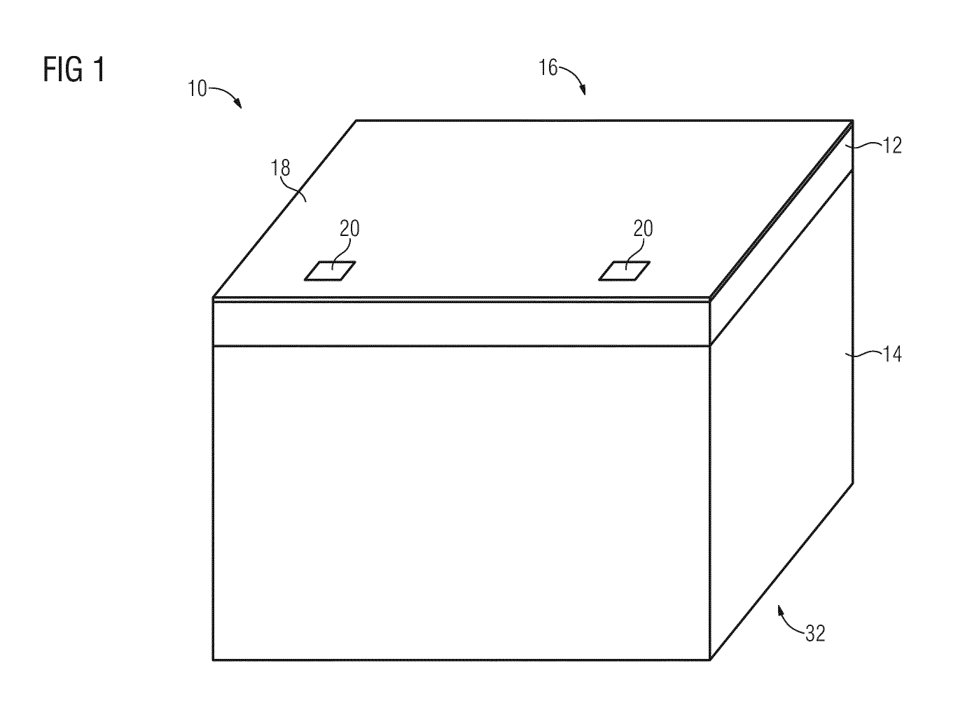

FIG. 1 depicts a schematic representation of a substrate material 10 in a perspective view. The substrate material 10 is formed by a semiconducting material, e.g., silicon. In this case, the substrate material 10 may be formed by monocrystalline or polycrystalline silicon. The substrate material 10 may also have a corresponding doping. As an alternative to this, it is also conceivable that the substrate material 10 is produced from some other known semiconductor material. The substrate material 10 has a first semiconductor layer 12 and a second semiconductor layer 14. The dimensions of the first and second semiconductor layers are not depicted to scale here. The first semiconductor layer 12 may have a thickness of several μm. The second semiconductor layer 14 has a thickness of several 100 μm. Between the first and the second semiconductor layer 12, 14, an insulating layer, which, for example, is formed from silica, may be additionally provided.

In FIG. 1, the substrate material 10 is depicted rotated. The first semiconductor layer 12, which is arranged on a rear side 16 of the semiconductor material 10, serves as a substrate for an integrated circuit 18, which is not depicted any more specifically here. The integrated circuit 18 is in particular produced on the basis of CMOS technology. The integrated circuit 18 may include transistors, which may be used later for the recording and evaluation of a sensor signal. Moreover, the integrated circuit 18 includes solder contacts 20, two of which are depicted here. The solder contacts 20 serve for the electrical contacting of the integrated circuit 18.

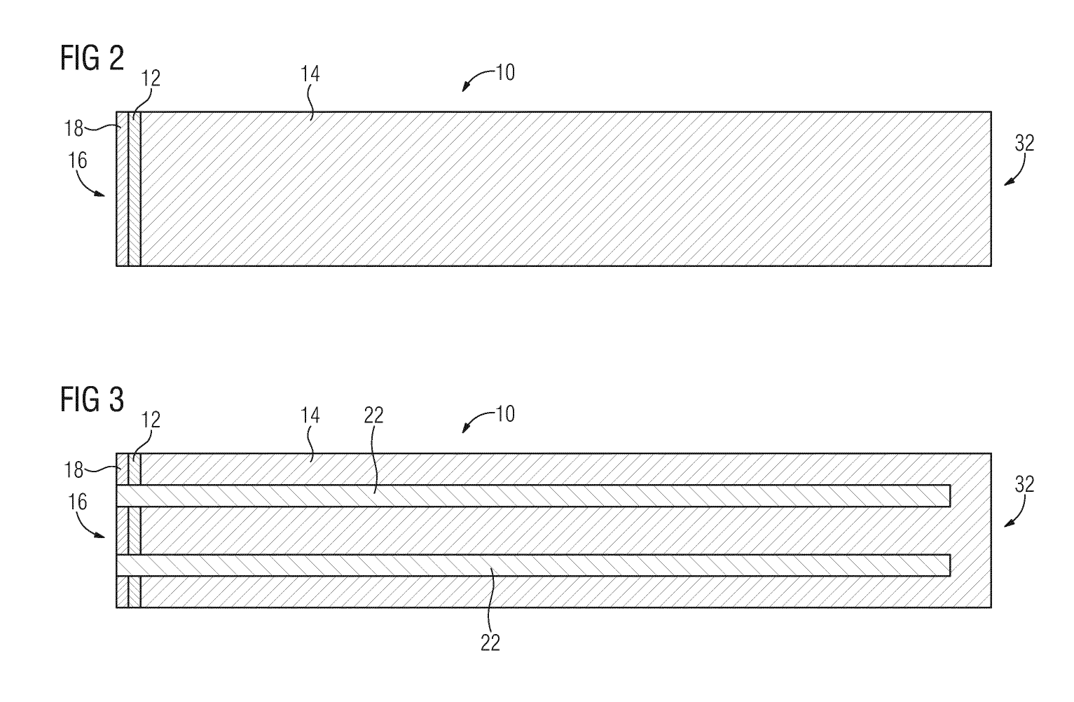

The production process for producing a microstructure with a plurality of thermocouples and a carrier element is presented below on the basis of FIGS. 2 to 5, which respectively depict a sectioned side view of the substrate material 10.

FIG. 2 depicts a sectioned side view of the substrate material 10 according to FIG. 1. After the production of the integrated circuit 18 in the first semiconductor material 12, the integrated circuit 18 is appropriately protected by a passivating or protective layer. For this purpose, for example, a silicon nitrite layer or an organic protective layer may be applied from the rear side 16 of the substrate material 10. A photoresist, which is appropriately structured by lithography, may be applied to the rear side 16 of the substrate material 10.

FIG. 3 depicts the substrate material 10 according to FIG. 2 after a further production act. Here, a plurality of wells 22 have been introduced into the substrate material. In FIG. 3, only two wells 22 are depicted for the sake of simplicity. The wells 22 have been introduced into the substrate material 10 from the rear side 16 of the substrate material 10. The wells 22 may have a round cross section, the diameter of which is below 10 μm. A microtechnical etching method may be used for the production of the wells 22. In particular, an electrochemical etching method is used here, e.g., the so-called PAECE method. For this purpose, the second semiconductor layer 14 may have a corresponding doping of, e.g., 5 to 200 Ωcm.

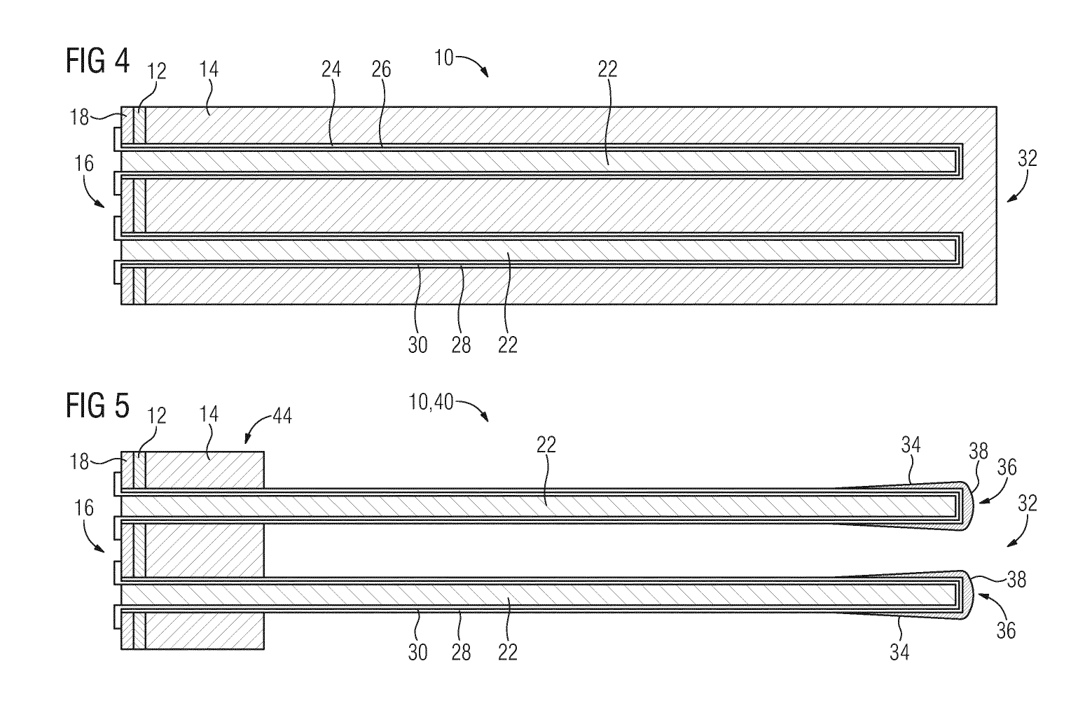

FIG. 4 depicts a representation according to FIG. 3, in which a further production act is depicted. Here, a first material 24 and a second material 26 have been introduced into the wells 22. The first material 24 and the second material 26 have two different Seebeck coefficients. The first material 24 and the second material 26 may be formed by appropriately doped semiconductor materials. In this case, the first material 24 is introduced into the wells 22 from the rear side 16 of the substrate material 10. The first material 24 may, for example, be introduced into the wells 22 by chemical vapor deposition (CVD). The first material 24 is introduced into the wells 22 in such a way that a thin layer of the first material 24 is deposited on the inner walls of the wells 22. Additionally, an insulating layer is introduced into the well. For this purpose, an electrically insulating material, (e.g., silica), may be used. After the application of the insulating layer, the second material 26 is applied to the insulating layer. A first sensor element 28, which has the form of a hollow cylinder, is formed by the first material 24. A second sensor element 30, which likewise has the form of a hollow cylinder, and which is arranged coaxially in the interior of the first sensor element 28, is formed by the second material 26.

The first material 24 and the second material 26 are applied such that the material 24, 26 is deposited not only in the wells 22, but also in certain regions on the rear side 16 of the substrate material 10, as is depicted in FIG. 4. The regions of the material 24, 26 that are located on the rear side 16 of the substrate material 10 serve for the electrical contacting with respect to the components of the integrated circuit 18.

FIG. 5 depicts a substrate material 10 according to FIG. 4 after a further production act. In this case, the substrate material 10 or the second semiconductor layer 14 has been removed, at least in certain regions, from the front side 32 opposite from the rear side 16. In this way, the thermocouples 34, which are formed by the first and second sensor elements 28, 30, are exposed at least in certain regions. Of the substrate material 10, only a carrier element 44 for the thermocouples 34 remains. In addition, the first sensor element 28 and the second sensor element 30 are electrically connected to one another at their respective free ends 36. Moreover, an absorption element 38 is respectively provided at the free ends 36 of the first and second sensor elements 28, 30 or of the thermocouples 34. The absorption element 38 may, for example, be formed by a polymer, which has a corresponding surface structure. The sensitivity of the thermocouples 34 may be increased by the absorption element 38.

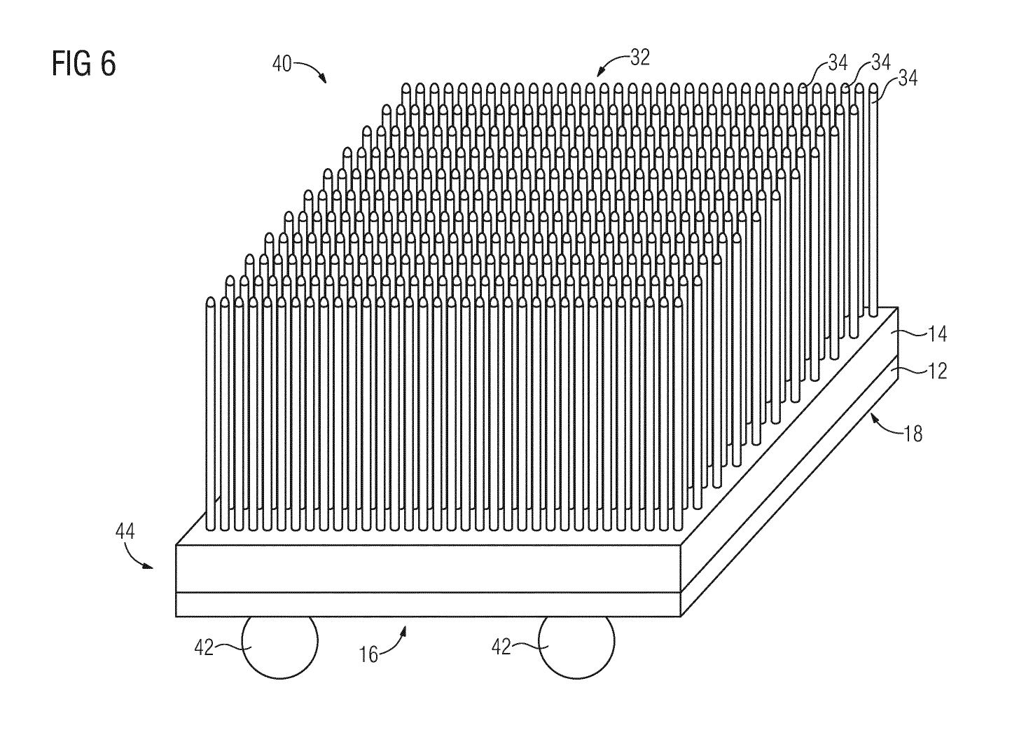

FIG. 6 depicts a schematic representation of the infrared sensor 40 according to FIG. 5 in a perspective representation. In this case, in addition to the solder contacts 20, which are not visible here, a solder 42 has been provided. In this way, the infrared sensor 40 may be electrically contacted and, for example, integrated in a thermal imaging camera.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. An infrared sensor comprising:
a microstructure with a plurality of thermocouples; and
a carrier element (44),
wherein each thermocouple of the plurality of thermocouples comprises a first sensor element having a first Seebeck coefficient and a second sensor element having a second Seebeck coefficient, the first sensor element and the second sensor element extending from a front side of the carrier element through the carrier element to a rear side of the carrier element, and the first sensor element and the second sensor element being electrically connected to one another in a region of the upper side of the carrier element, and
wherein the carrier element forms a substrate for an integrated circuit on the rear side of the carrier element and comprises at least one component that is electrically connected to the first sensor element and the second sensor element.

2. The infrared sensor as claimed in claim 1, wherein the at least one component is configured to record the electric voltage between the first sensor element and the second sensor element.

3. The infrared sensor as claimed in claim 1, wherein the integrated circuit comprises an amplifier, an analog-to-digital converter, or the amplifier and the analog-to-digital converter.

4. The infrared sensor as claimed in claim 1, wherein the integrated circuit comprises a temperature sensor for recording a temperature on the rear side of the carrier element.

5. The infrared sensor as claimed in claim 1, wherein the first sensor element is formed as a hollow profile and the second sensor element is arranged in the first sensor element.

6. The infrared sensor as claimed in claim 1, wherein the integrated circuit comprises solder contacts.

7. A method for producing a microstructure with a plurality of thermocouples and a carrier element, the method comprising:
providing a substrate material, which forms a substrate for an integrated circuit;
forming the integrated circuit on a rear side of the substrate material, the integrated circuit comprising at least one component;
forming a plurality of wells, which extend from the rear side of the substrate material into the substrate material;
arranging a first material with a first Seebeck coefficient in a respective interior space of a first predetermined number of the plurality of wells to form a respective first sensor element;
arranging a second material with a second Seebeck coefficient in a respective interior space of a second predetermined number of the plurality of wells to form a respective second sensor element; and
removing the substrate material, starting from a front side of the substrate material, and thereby exposing at least one region of the first sensor element, the second sensor element, or the first sensor element and the second sensor element.

8. The method as claimed in claim 7, wherein the first material is arranged in the respective interior space of the wells, and following the arrangement of the first material, an electrically insulating material is applied to the first material and then the second material is applied to the electrically insulating material.

9. The method as claimed in claim 7, wherein the substrate material is a semiconductor material having a first semiconductor layer, a second semiconductor layer, and an insulating layer arranged between the semiconductor layers.

10. The method as claimed in claim 9, wherein, for forming the wells, the first semiconductor layer is etched by dry-chemical etching and the second semiconductor layer is etched by electrochemical etching.

11. The method as claimed in claim 8, wherein the substrate material is a semiconductor material having a first semiconductor layer, a second semiconductor layer, and an insulating layer arranged between the semiconductor layers.

12. The method as claimed in claim 11, wherein, for forming the wells, the first semiconductor layer is etched by dry-chemical etching and the second semiconductor layer is etched by electrochemical etching.

13. The infrared sensor as claimed in claim 2, wherein the integrated circuit comprises an amplifier, an analog-to-digital converter, or the amplifier and the analog-to-digital converter.

14. The infrared sensor as claimed in claim 13, wherein the integrated circuit comprises a temperature sensor for recording a temperature on the rear side of the carrier element.

15. The infrared sensor as claimed in claim 14, wherein the first sensor element is formed as a hollow profile and the second sensor element is arranged in the first sensor element.

16. The infrared sensor as claimed in claim 15, wherein the integrated circuit comprises solder contacts.

17. The infrared sensor as claimed in claim 3, wherein the integrated circuit comprises a temperature sensor for recording a temperature on the rear side of the carrier element.

18. The infrared sensor as claimed in claim 17, wherein the integrated circuit comprises solder contacts.

19. The infrared sensor as claimed in claim 3, wherein the integrated circuit comprises solder contacts.

20. The infrared sensor as claimed in claim 4, wherein the integrated circuit comprises solder contacts.
